(19) United States
(12) Patent Application Publication
(10) Pub. No.: US 2018/0062424 A1
(43) Pub. Date: Mar. 1, 2018

(54) Energy Conserving Thermoelectric Generating Chimney Cap

(71) Applicants: Aaron T Fleischer, Kensington, NH (US); Gary D Fleischer, Kensington, NH (US)

(72) Inventors: Aaron T Fleischer, Kensington, NH (US); Gary D Fleischer, Kensington, NH (US)

(21) Appl. No.: 15/254,496

(22) Filed: Sep. 1, 2016

(51) Int. Cl. H02J 7/35; H01L 35/30; F23J 13/00

(52) U.S. Cl. CPC H02J 7/35; F23J 13/00; H01L 35/30

(57) ABSTRACT

A chimney cap system is comprised of a support base securable to the top of a chimney flue and a device which sits on top of the chimney blocking rain and debris from falling into the open flue. It can be ornamental as well as functional. The sides often have screens of some type to allow the effluent hot gasses and smoke to exit the top of the flue passively while capturing sparks and debris leaving that may pose a fire hazard. Additionally, significant energy is wasted out of the top of the chimney as heat and super heated gasses are vented wastefully into the outside environment. A thermoelectric generator, TEG, utilizing the temperature gradient between the gasses inside the flue and the ambient air outside the flue to generate electricity via the Seebeck effect is incorporated into a chimney cap to capture the otherwise wasted energy and recycle it.

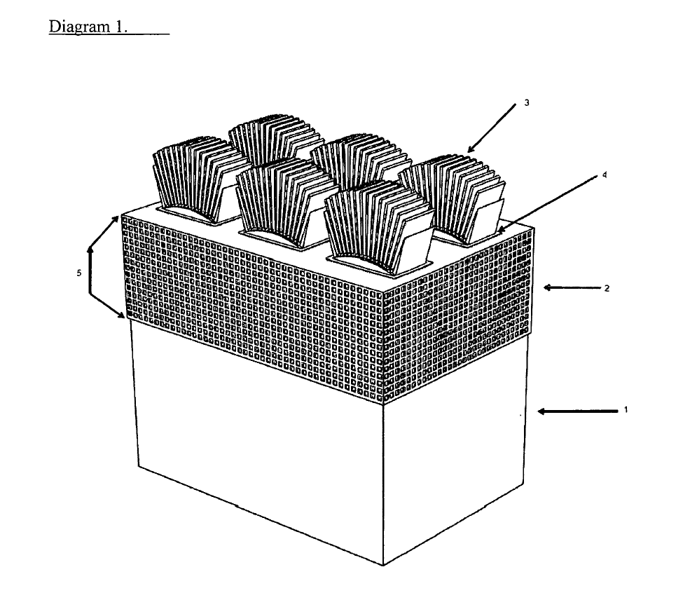

### BACKGROUND OF INVENTION

### 1. Field of Invention

This invention relates to chimney caps, energy conservation, and electrical power generation devices. More particularly, this invention relates to an improved chimney cap which uses a thermoelectric generator, utilizing the wasted heat out of the chimney and temperature gradient with the outside ambient temperature to generate electrical energy for use or storage from otherwise wasted heat energy. In its most basic form, the invention relates to recovery of energy that can be captured as electricity when a heat gradient exists whenever effluent gases leave a structure and are discharged to the exterior.

### 2. Prior Art

In homes and other buildings having a fireplace or combustion furnace vented to the outside environment through a chimney. The fireplace opening or furnace unit is connected to a chimney flue which is open to the outside of the building. When in use, the combustion products from the fireplace or furnace pass up through the flue and exit the chimney as hot gasses and heat.

Sometimes burning material or sparks may be emitted from the top of the chimney posing a potential fire risk. The chimney flu also provides a potential ingress that allows materials such as rain or snow to enter the chimney and fall down the flue, which may cause damage. Chimney caps with or without screens, which are attached at the top of the chimney limit the amount of hot particles which pass into the environment. Further, these screens prevent small animals, such as birds, from entering the chimney flue. To mitigate all of these risks, many chimneys have been covered with some form of chimney cap that forms a roof like structure above the flu opening, allowing effluent to exit while acting as shield or screen for solids to exit or materials to enter the flue. These chimney caps come in many decorative and practical forms.

A number of chimney caps have been produced which are mounted on the top of the chimney to provide a cover to improve ventilation, protection, and appearance. Various types of chimney caps are available. For example, one cap designed to improve ventilation up the chimney is shown in U.S. Pat. No. 8,696,416. That invention, however, does not include any way to capture wasted energy from the gasses. This invention is distinctly different from other chimney cap inventions in its ability to generate electricity utilizing thermoelectric effects.

Some chimney top devices have been described that utilize mechanical turbines which capture the flow of gasses through a flue to turn the turbines and generate electricity as in U.S. Pat. No. 20040183309 A1. This invention is distinctly different in that the electricity generation is from a thermoelectric module and not a mechanical turbine which can age and fail and require mechanical maintenance. It utilizes electrochemical processes and not mechanical processes to generate electricity. this invention does not require any moving parts and is easily attached to a manageable chimney cap or chimney top mounted device.

Other prior art has been directed at capturing the heat in the lining of a chimney flu or on the outside surface of a stove or furnace by using thermolectric generation. One example is shown as an insert into the wall of a stove in US Pat. App. Pub. 2008/0245352 A1. Another example utilizes the heat differential in the forced air exchanger of a gas-fired furnace to power a thermoelectric module in U.S. Pat. No. 5,427,086. Many of the strategies for integrating a thermoelectric generating module into the structure of a flue, such as disclosed in U.S. Pat. No. 5,427,086, require integration at the time of manufacture and create access problems for servicing. This invention is distinct from that prior art in that it incorporates the thermoelectric generating modules and capability into a chimney cap and not the walls of the chimney. This is a significant difference in that it can be easily accomplished separate from the fabrication of the chimney, does not required access to the sides of the flue inside the chimney, allows easy retrofitting or conversion to a preexisting chimney/flue, and can be easily accessed or removed for service or replacement.

It is the object of this invention to create a thermoelectric generating system which is not integrated into the structural elements of the chimney, flu, or combustion chamber, but rather attached or integral to the chimney-top device placed on the external opening of the flue.

It is a still further object of the invention to provide a chimney-top device that functions in all of the desired normal functions of a chimney cap, while still producing electricity from otherwise wasted vented heat and exhaust gasses.

It is a still further object of the invention to provide the thermoelectric capabilities to a chimney top device that can be retrofitted to an already existing chimney and provides easy external access for installation and maintenance.

It is a still further object of the invention to provide external access to the thermoelectric generating module in order to allow the attachment various potential electric devices or storage arrays.

### SUMMARY OF INVENTION

The invention is an improved chimney-top device that serves as both a functional chimney cap and a thermoelectric generator. The chimney cap and thermoelectric generating system is comprised of a support base securable to the top of a chimney flue, a chimney cap secured to the top of the support base, a thermoelectric, Seebeck or Peltier, type generating module or series of modules, and electrical connections that allow appropriate and convenient access to the generated electrical power. The thermoelectric generator, TEG, utilizes the temperature gradient between the hot side and the cold side of the TEG module to generate electricity using the Seebeck effect. In this invention, the hot side of the TEG would be mounted on or integrated into the flu chimney cap device, facing the flu, and the cold side of the TEG would be facing away from the flue and exposed to the ambient air, maximizing the temperature difference between the effluent and the outside air. The energy generated can be utilized to feed a local or commercial power grid, power local devices, or fill an attached battery or storage device.

In an alternate preferred embodiment, the chimney cap would provide directional exhaust or airflow mechanisms to prevent the effluent gasses from approaching close to the cold side of the TEG modules. Additional, active or passive heat sinks would be attached to the cold side of the TEG, further maximizing the temperature gradient and cooling the TEGs to provide maximal electrical generation.

In an alternate preferred embodiment, the chimney cap would include heat conductive tines or appendages that extend down into the flue in order to capture and deliver more heat to the hot side surface of the TEG.

In one example of the utilization of the device, the TEG chimney cap could be placed atop a residential chimney that vents both the house's fireplace and furnace. In cold weather environments, ice damming on roofs is a common problem. Electrical heating wires are often utilized on the lower roof lines to melt ice and prevent damming. This requires the use of additional electricity wasted as heat to melt the ice and creating a new financial and environmental cost in energy generation. All the while, in order to heat the house in that cold environment, combustion in the furnace is spilling copious wasted heat out of the chimney top. In this example, the TEG chimney cap could be utilized to generate electricity from the wasted chimney heat that could help power the ice melting wires and reduce the financial and environmental costs. In an even more elegant nuance of this system, the colder the outside temperature, the more heat is generated in the chimney, making the hot side hotter. All the while, the outside temperature is colder, making the temperature gradient, and therefore, the power generation, more efficient. In other words, the colder it is outside, the more electricity gets potentially generated. Likewise, in periods of low heat generation and warmer ambient temperatures TEG electrical generation will be decreased or stopped and the attached devices will effectively be turned off.

### BRIEF DESCRIPTION OF THE DRAWING

This invention will now be described with reference to the accompanying drawing in which the overall drawing represents the most basic embodiment of the invention:

Diagram 1:

1. Refers to the chimney including 1 or more chimney flues.

2. Refers to the screen-like portion of a chimney cap.

3. Refers to heat sinks affixed to the cold-side of the thermoelectric generators.

4. Refers to the thermoelectric, Seebeck or Peltier generator modules with the hot-side mounted on or incorporated into the roof surface of the chimney cap and facing the direction of the flue and the cold-side facing outward into the open environment against the heat sinks.

5. Refers to the overall chimney top device with some mounting hardware or apparatus to attach it to the chimney top.

### DETAILED DESCRIPTION OF THE INVENTION

The description below pertains to the fundamental elements of the invention and several illustrative embodiments. Although many variations of the invention may be envisioned by one skilled in the art, such variations and improvements are intended to fall within the compass of this disclosure. Thus, the scope of the invention is not to be limited in any way by the disclosure below.

One embodiment of the invention is comprised of a Seebeck thermoelectric generating (TEG) module or unit attached or mounted to a chimney cap or device intended to cover, protect, or ornament the top of a chimney or flue. The TEG module may be integrated into the substance of the chimney cap (i.e. an integral part of the structure and design of the cap) or mounted appropriately onto the already existing chimney cap surface. In a Seebeck TEG, one side of the TEG is designated to be the “hot” side and the other as the “cold” side. The hot side is by necessity oriented toward the flue and the cold side away from the flue. The function and power of the TEG to generate electricity is dependent on the material properties of each individual TEG and the temperature difference between the 2 sides. The TEG module would be connected in an electric circuit to any variety of electrical devices or storage units to utilize the generated electricity. As such, any number of alternative configurations and embodiments could be used to maximize the efficiency of TEG function and power generation in this invention.

In one such embodiment, the TEG may take the form of several TEGs electrically linked to one another in series or in parallel or existing separately, but utilizing the same chimney as a heat source. The generated electrical power could then be directed collectively into to one device or separately into any of several devices.

In another such embodiment, the efficiency of heating the hot side of the TEGs could be improved by employing in conjunction with or attaching to the undersurface of the chimney cap a heat collecting device or attachment or series of heat collecting devices or attachments. An example of one such attachment may be tines made of an appropriate heat conducting material, such as a conductive metal, that are attached to the hot side of the chimney cap and extend down the flue toward the heat source, fire, or furnace and conduct heat directly to the hot side of the chimney cap and transitively the hot side of the TEG. In another example, a duct or damper could be inserted within the flue to maximize the delivery of hot effluent gasses to the area directly against apposed to the hot side of the TEG.

In another embodiment, the temperature difference between the hot and cold sides could be maximized by attaching active or passive heat sink devices to the cold side of the TEGs. These would help to vent heat into the cold external atmosphere more efficiently and increase the thermal gradient between the hot and cold sides of the TEG. In some embodiments, it may be desirable to include ornamental properties to the heat sinks, as they would be exposed to the outside environment and be potentially visible in ways that effect the aesthetics of the installation and device.

The electricity generated by this invention can be utilized to power any assortment of electrical devices or stored, as in a battery or capacitor, for later use or even fed back to the power grid. In one such embodiment, the electricity could be used to power heating wires attached along the roof adjacent to or near the chimney in order to melt snow and ice to keep the roof line clear for drainage and prevent ice damming. In another use, the TEGs could be hooked to a light or lamp to provide illumination or a visual indication of the temperature inside the flue. In another use, the TEGs could be attached to a power grid to add power to an existing electrical infrastructure or to feed into the commercial grid. In another use, the TEG array could be attached to an electrical storage array to smooth peaks and lulls in generation.

In another embodiment, the chimney cap and TEGs may include a light or light integral to or attached elsewhere on the chimney cap or chimney that might serve as a visual marker of the location of the chimney in space as a warning or navigational aid, as in an industrial smokestack, drawing its power in part or in whole from the TEG.

In another embodiment, the TEG or array of TEGs can be appropriately attached to, mounted on, or integrally manufactured as part of a functional chimney cap in which the design of the chimney cap itself is integral to the maximization of the thermal gradient between the hot and cold side of the TEGs. For example, the chimney cap itself may function as a device to channel heat or heated effluent asses to the hot side of the TEGs. Likewise, the design of the chimney cap may integrally function as a heat sink to help cool the cold side of the TEG or TEG array. In another example, the chimney cap design may direct hot effluent gasses away from the space around the heat sinks after allowing them to heat the hot side of the TEGs.

1. A thermoelectric generating chimney cap system which includes at least a means to attach a device, comprised of a thermoelectric generating module (TEG) or combination of TEGs, to be positioned above or astride open end of a chimney flue in order to utilize the vented thermal energy and super heated effluent materials to heat the hot side of a Seebeck or Peltier or other style TEG while utilizing the temperature gradient between the materials and heat vented from the top of the flue and the ambient outside temperature to generate electricity via the Seebeck effect for use or storage via an electrical interface or outlet attached to the output wires from the TEG or array of TEGs.

2. A thermoelectric generating chimney cap system in which the system is fabricated from a thermoelectric generating module (TEG) or TEGs which are mounted, bonded, or otherwise attached to the surface of a chimney cap in order to position them astride the opening of the flue covered by the chimney cap system. The method of mounting or attachment allows thermal conductivity between the surface of the cap and the surface of the TEG.

3. A thermoelectric generating chimney cap system according to claim 2 characterized by fabrication in which the TEG or TEGs are an integral structural part of the chimney cap and not simply attached or mounted to the surface of the cap.

4. A thermoelectric generating chimney cap system according to claim 1 characterized in that the chimney cap system contains a complete chimney cap including a roof, upright supports, and a means to attach it to the chimney or flue.

5. A thermoelectric generating chimney cap system according to claim 4 characterized in that the chimney cap may include walls, solid or reticulated, that provide protection against expelling burning material and prevent undesired entry of foreign object and animals into the flue, while preserving the function of the TEG array.

6. A thermoelectric generating chimney cap system according to claim 1 characterized in that cold surface of the TEG or array of TEGs may be thermally connected to a heat sink or system of heat sinks that may utilize passive or active dissipation of heat to maximize the thermal gradient between the hot and cold side of the TEGs.

7. A thermoelectric generating chimney cap system according to claim 1 characterized in that the combination of the chimney cap design TEGs is ornamental and provides a desired aesthetic overall quality for decoration of the top of the chimney and flue.

8. A thermoelectric generating chimney cap system according to claim 7 characterized in that the addition of heat sinks devices to the cold or ambient side of the TEG and chimney cap is also decorative and meant to add to the design and aesthetic quality of the chimney cap.

9. A thermoelectric generating chimney cap system according to claim 1 characterized in that it may be attached to an electrical distribution system that allows the attachment of one or more external electrical devices or systems.

10. A thermoelectric generating chimney cap system according to claim 9 characterized in that one or several electrical devices which utilize or store the generated energy in part or in whole are attached.

11. A thermoelectric generating chimney cap system according to claim 10 characterized in that the energy generated powers a light or device that marks the position of the chimney in space to act as a safety feature or aid to navigation powered by the conserved energy in part or in whole recycled from the waste vented out the top of the chimney.

12. A thermoelectric generating chimney cap system according to claim 10 characterized in that it is attached to roof mounted electrical devices such as heating wires to prevent ice dams or decorative lighting, powered in part or in whole by the recaptured energy otherwise wasted into the ambient environment from the top of the chimney.

13. A thermoelectric generating chimney cap system according to claim 1 characterized in that the output is attached to an electrical device that adds the electricity to a power grid or system allowing it to be used as supplemental electricity to power devices with a second source of power, thus decreasing the energy required from the second source and recycling or conserving the energy otherwise lost to the ambient environment in the form of heat and hot effluent vented form the top of the chimney.

14. A thermoelectric generating chimney cap system according to claim 1 or 4 characterized by chimney cap designed to functional vented the effluent and heat to the side after heating the TEGs and passively or actively direct the outflow deliberately away from the local environment surrounding the cold side of the TEG or array of TEGs.

15. A thermoelectric generating chimney cap system according to claim 1 or 4 characterized by appendages or attachments to promote thermal conduction to the hot side surface of the TEGs.

16. A thermoelectric generating chimney cap system according to claim 15 characterized by thermal conducting appendages which extend down the inside of the flu and conduct heat directly to the hot side of the chimney cap or TEGs.

17. A thermoelectric generating chimney cap system according to claim 15 characterized by fabrication of the appendages in which they may be integral to the design of the chimney cap or optionally added after fabrication of the system while maintaining thermal conductivity and structural support.

18. A thermoelectric generating chimney cap system according to claim 1 or 4 characterized by handles or adaptation and a reversible means of attachment to the chimney that allow removal for cleaning, servicing, or replacement.

19. A thermoelectric generating chimney cap system according to claim 1 characterized by multiple TEGs arranged in a system electrically in parallel or in series to improve conservation and power generation.

20. A thermoelectric generating chimney cap system according to claim 19 characterized by stacking the TEGs so that the hot side of one TEG acts as a heat sink cooling the cold side of the adjacent TEG as a pair or stack of multiple TEGS.

21. A thermoelectric generating module stack according to claim 20 characterized by maximizing the exposure to a limited surface area astride the opening of the flue or hot surface of the chimney cap or the cold surface of an external heat sink.

22. A thermoelectric generating chimney cap system according to claim 1 or 4 characterized by different designs of the chimney cap, such as flat, domed, or peaked, which change the gas flow and thermal characteristics inside the chimney cap to produce desired effects in concentrating heat and gas flow around the hot side of the TEGs.

23. A thermoelectric generating chimney cap system according to claim 9 characterized by attachment to a local storage array or battery to save power generated at peak times and recover it during generation lulls.

24. A thermoelectric generating chimney cap system according to claim 9 characterized by an attachment to the local power grid to inject power into the building or structure through its already existing electrical infrastructure.

25. A thermoelectric generating chimney cap system according to claim 9 characterized by attachment to the commercial power grid allowing the recycled energy to be fed back to the power company.

26. A thermoelectric generating system which includes at least a means to attach a device, comprised of a thermoelectric generating module (TEG) or combination of TEGs, to be positioned at any point in a residence or building where heat escapes in order to utilize the vented thermal energy and super heated effluent materials to heat the hot side of a Seebeck or Peltier or other style TEG while utilizing the temperature gradient between the materials and heat vented and the outside temperature to generate electricity via the Seebeck effect for use or storage via an electrical interface or outlet attached to the output wires from the TEG or array of TEGs.
